(19) United States
(12) Patent Application Publication
(10) Pub. No.: US 2006/0267190 A1
(43) Pub. Date: Nov. 30, 2006

(54) Semiconductor device, laminated semiconductor device, and method for producing semiconductor device

(75) Inventors: Tomonori Terada, Fukuyama-shi (JP); Toshihisa Gotoh, Fukuyama-shi (JP)

Correspondence Address: NIXON & VANDERHYE, PC, 901 NORTH GLEBE ROAD, 11TH FLOOR, ARLINGTON, VA, 22203, US

(73) Assignee: Sharp Kabushiki Kaisha, Osaka (JP)

(21) Appl. No.: 11/438,281

(22) Filed: May 23, 2006

(30) Foreign Application Priority Data
May 24, 2005 (JP) 2005-151624

(51) Int. Cl. H01L 23/34

(52) U.S. Cl. 257/723

(57) ABSTRACT

A method according to the present invention for producing a semiconductor device includes the step of forming a connecting electrode for allowing connection with an outside electrode. The step includes the sub-steps of (i) forming, in a silicon substrate, a concave section whose inner wall is covered by a conductive layer, (ii) filling the concave section with a filler made of a material different from a material of the conductive layer, and (iii) exposing the conductive layer from a bottom surface of the silicon substrate. As a result, it is possible to speedily produce a semiconductor device favorably applicable to a laminated semiconductor device.

This non-provisional application claims priority under 35 U.S.C. § 119(a) on Patent Application No. 2005-151624 filed in Japan on May 24, 2005, the entire contents of which are hereby incorporated by reference.

### FIELD OF THE INVENTION

The present invention relates to (i) a multi-chip semiconductor device (laminated semiconductor device) including a plurality of semiconductor chips (semiconductor devices), (ii) a semiconductor chip favorably applicable to the multi-chip semiconductor device, and (iii) a method for producing the semiconductor chip.

### BACKGROUND OF THE INVENTION

Recently, in a main portion of computers and communication devices, there is frequently used a large-scale integrated circuit (LSI chip) in which a lot of semiconductor elements such as transistors and resistors are connected with one another so as to form an electric circuit and integrated on a substrate. Therefore, an ability of a chip has a great influence on an ability of a whole device.

Further, in order to enhance the ability of the whole device, there is proposed a so-called multi-chip semiconductor device (laminated semiconductor device) on which a plurality of LSI chips are laminated. With reference to FIGS. 4 and 5, the following explains multi-chip semiconductor devices disclosed in Document 1 (Japanese Unexamined Patent Publication No. 223833/1998 (Tokukaihei 10-223833; published on Aug. 21, 1998) (corresponding to: U.S. Pat. No. 6,087,719 (published on Jul. 11, 2000); U.S. Pat. No. 6,383,837 (published on May 7, 2002); U.S. Patent No. 2002/028532 (published on Mar. 7, 2002); U.S. Pat. No. 6,809,421 (published on Oct. 26, 2004); and U.S. Patent No. 2005/014311 (published on Jan. 20, 2005) and Document 2 (Japanese Unexamined Patent Publication No. 281982/2004 (Tokukai 2004-281982; published on Oct. 7, 2004).

FIGS. 4 and 5 are cross sectional views illustrating conventional multi-chip semiconductor devices.

As illustrated in FIG. 4, a conventional multi-chip semiconductor device 800 has a structure in which three chips 801a to 801c (semiconductor devices; the chips 801a to 801c are generically termed a “chip 801 (801a to 801c)” hereinafter) are laminated. The chip 801 (801a to 801c) is constituted of silicon substrates 802 having top surfaces on which semiconductor elements are integrated, multi-layered wiring layers 803 for connecting the semiconductor elements with each other, and connecting plugs (metal plugs 804 and insulating films 805) which serve as connecting electrodes for electrically connecting the chips with each other.

The multi-layered wiring layers 803 have inter-layer insulating films which cover the top surfaces of the silicon substrates 802. Further, the connecting plugs are formed in penetrating holes which penetrate the inter-layer insulating films and the silicon substrates 802. Further, the connecting plugs are constituted of the metal plugs 804 and the insulating films 805 which are formed between the penetrating holes and the metal plugs 804.

Further, pads 806 are provided in the multi-layered wiring layers 803 in the chip 801 (801a to 801c). The metal plug 804 in the chip 801a is electrically connected with the pad 806 in the chip 801b via a solder bump 808. In the same way, the metal plug 804 in the chip 801b is electrically connected with the pad 806 in the chip 801c via the solder bump 808. In this way, the chips 801a to 801c are electrically connected with one another.

The following explains a method for producing the chip 801 (801a to 801c), particularly a method for forming the metal plug 804.

First, there is provided the silicon substrate 802 having the top surface on which the inter-layer insulating film is formed. By carrying out etching, there is formed a hole whose depth is approximately 100 μm and which penetrates the inter-layer insulating film but does not penetrate the silicon substrate 802. The whole surface of the silicon substrate 802 is covered by an insulating film which serves as the insulating film 805. Thereafter, a metal film which serves as the metal plug 804 is formed so as to be thick enough to flood out of the hole. Subsequently, the metal film and the insulating film are partially removed by carrying out CMP (Chemical Mechanical Polishing) or etch-back so that the top surface of the inter-layer insulating film is exposed. In this way, there is formed a structure in which the metal film serving as the metal plug 804 is embedded in the hole.

Next, a multi-layer wiring structure, the pad 806 and the like are formed. Thereafter, a bottom surface of the silicon substrate 802 is partially removed so that a bottom of the metal plug 804 is exposed from the bottom surface of the silicon substrate 802. In this way, the metal plug 804 illustrated in FIG. 4 is formed.

Further, Document 2 discloses a semiconductor device 900 (layered semiconductor device) illustrated in FIG. 5. The semiconductor device 900 includes an interposer substrate 901. Semiconductor chips 906a to 906c (semiconductor devices) having different sizes are disposed in this order above the interposer substrate 901 by carrying out face-down bonding so that the semiconductor chip 906a is positioned nearest to the interposer substrate 901.

The following details a structure of the semiconductor device 900. The semiconductor device 900 includes: the interposer substrate 901; a wiring pattern 902 which is formed on a top surface of the interposer substrate 901; a pad 904 which is formed on a bottom surface of the interposer substrate 901 and which is electrically connected with the wiring pattern 902 via a connecting member 905; a solder bump 903 which is disposed under the pad 904 and which serves as an external packaging terminal connected with the pad 904.

Further, in order to electrically connect the wiring pattern 902 with the semiconductor chips 906a to 906c, the semiconductor device 900 includes electrode-drawing pads 907a to 907c and metal posts 908a to 908c.

Further, Document 2 discloses a method for forming the metal posts 908a to 908c illustrated in FIG. 5. In the method, a Cu layer is formed on the electrode-drawing pads 907a to 907c by carrying out selective metal plating.

Further, it is general that a semiconductor chip can be made thinner as far as approximately 50 μm. This was explained in a lecture in “New Challenge to Polishing Back Surface of Wafer—as thin as possible, foldable like paper—” held by The Semiconductor Industry News (Sangyo Times, Inc). Namely, in a case of a semiconductor chip formed in accordance with a technique disclosed in Document 2, too, it is necessary to cause a metal post to have a thickness of 30 μm or more.

Further, in Document 1, a filling-by-plating process is performed with respect to a metal (Cu) so as to form a connecting electrode material in producing a chip used for a conventional multi-chip semiconductor device. However, the filling-by-plating process has very low production efficiency, i.e., 2 to 6 hours/wafer. In Document 2, Cu is formed in accordance with a method in which Cu is selectively grown by using a resist mask. However, as with the method disclosed in Document 1, it takes much time to grow a metal (Cu) (the news release of Oki Electric Industry Co, Ltd., dated Nov. 24, 2004, states that it takes 4 hours to perform metal plating of Cu for a wafer level chip size package).

Namely, in a case of the filling-by-plating process disclosed in Document 1 and in a case of selective metal plating disclosed in Document 2, there is such a disadvantage that it takes much time to grow a metal (Cu).

### SUMMARY OF THE INVENTION

An object of the present invention is to provide (i) a method which allows for efficient and speedy production of a semiconductor device, (ii) a semiconductor device, and (iii) a laminated semiconductor device including the semiconductor device.

In order to achieve the foregoing object, a method according to the present invention for producing a semiconductor device includes the step of forming, in a substrate having semiconductor elements on a top surface of the substrate, a connecting electrode for electrically connecting the semiconductor elements with an outside electrode, said step further including the sub-steps of: (i) forming a concave section by forming an opening on the top surface of the substrate and coating an inner wall of the opening with a conductive layer; and (ii) exposing the conductive layer from a bottom surface of the substrate.

With the method, the conductive layer can be used as the connecting electrode which penetrates the substrate. Namely, a connecting electrode having a concave shape is formed. As a result, it takes less time to form the connecting electrode than a conventional method for producing a semiconductor device. Therefore, it is possible to reduce a time necessary for production of a semiconductor device.

Further, a semiconductor device according to the present invention includes a substrate and semiconductor elements provided on a top surface of the substrate, said substrate including (i) a first connecting region provided on the top surface of the substrate so as to allow connection with an outside electrode, (ii) a second connecting region provided on a back surface of the substrate so as to allow connection with an outside electrode, and (iii) a connecting electrode which penetrates the substrate and allows electrical connection with the first connecting region and the second connecting region, at least a part of said connecting electrode including a core and a conductive layer surrounding the core in a cross sectional face parallel to the top surface of the substrate, and said core being made of a material different from a material of the conductive layer.

With the arrangement, the connecting electrode includes the core made of the material different from the material of the conductive layer. Therefore, it takes less time to form the connecting electrode than a case where the inside of the connecting electrode is made of the same material as the conductive layer.

Further, a laminated semiconductor device according to the present invention is obtained by laminating a plurality of semiconductor devices, and semiconductor devices adjacent to each other, out of the semiconductor devices, are electrically connected with each other via a first connecting region on one of the semiconductor devices adjacent to each other and a second connecting region on another of the semiconductor devices adjacent to each other.

With the arrangement, the laminated semiconductor device according to the present invention includes a semiconductor device including an electrode which penetrates the substrate. It is easy to laminate such semiconductor device, so that it is easy to produce the laminated semiconductor device. Further, it takes less time to produce the semiconductor device, so that it takes less time to produce the laminated semiconductor device including the semiconductor device.

For a fuller understanding of the nature and advantages of the invention, reference should be made to the ensuing detailed description taken in conjunction with the accompanying drawings.

### BRIEF DESCRIPTION OF THE DRAWINGS

FIGS. 1(a) to 1(j) are cross sectional views illustrating, in the order of steps, how to produce a semiconductor device according to an embodiment of the present invention.

FIG. 2 is a cross sectional view illustrating a multi-chip semiconductor device obtained by laminating a semiconductor chip according to the embodiment of the present invention.

FIG. 3 is a plan view illustrating how the semiconductor chip according to the embodiment of the present invention is laminated.

FIG. 4 is a cross sectional view illustrating a conventional multi-chip semiconductor device.

FIG. 5 is a cross sectional view illustrating a conventional multi-chip semiconductor device.

### DESCRIPTION OF THE EMBODIMENTS

Structure of Semiconductor Device

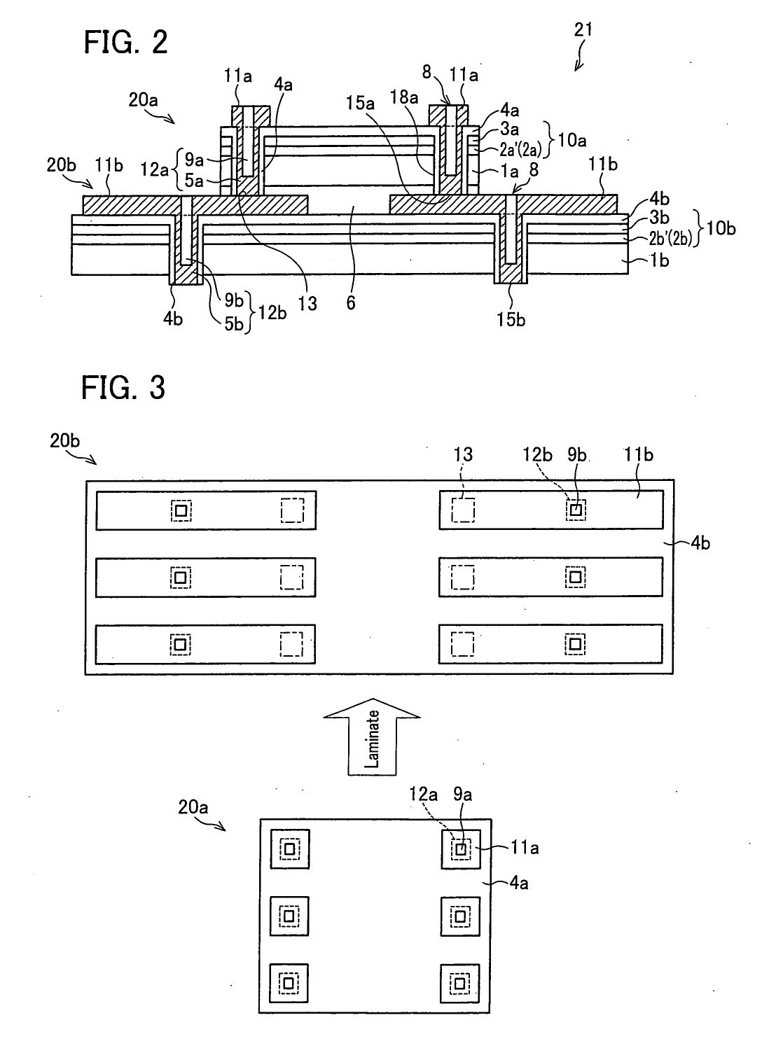

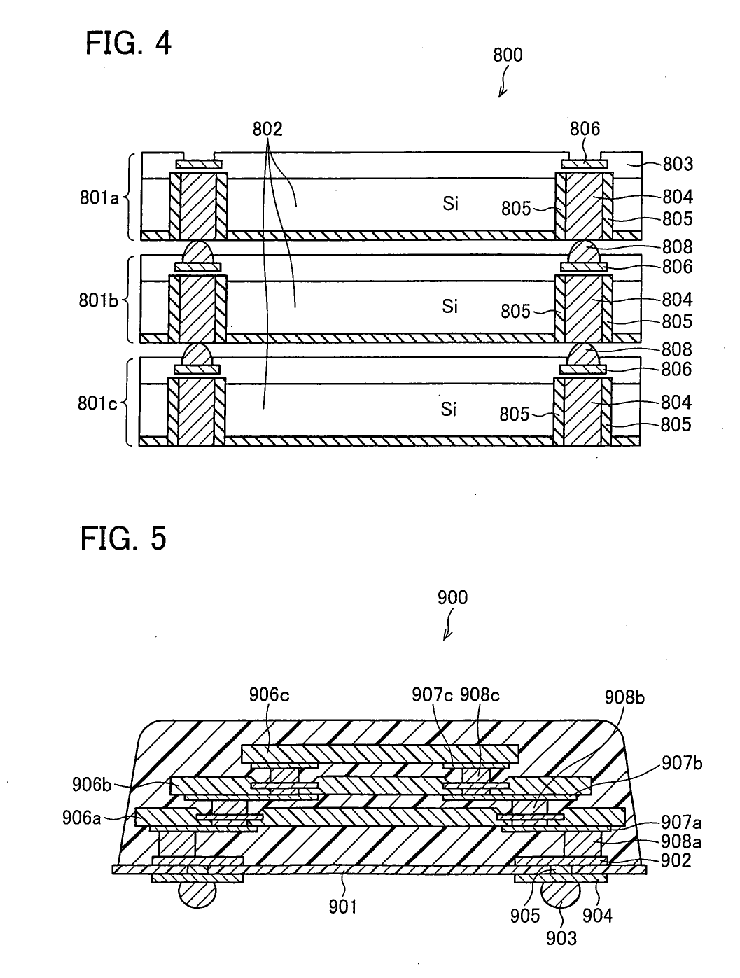

With reference to FIGS. 2 and 3, the following explains a semiconductor device according to an embodiment of the present invention.

FIG. 2 is a cross sectional view illustrating a multi-chip semiconductor device (laminated semiconductor device) including a semiconductor chip (semiconductor device) according to the present embodiment. Further, FIG. 3 is a plan view illustrating the semiconductor chip illustrated in FIG. 2.

As illustrated in FIG. 2, a multi-chip semiconductor device (laminated semiconductor device) 21 according to the present embodiment includes a plurality of semiconductor chips (semiconductor devices) (semiconductor chips 20a and 20b in the example illustrated in FIG. 2). Each of the semiconductor chips is termed a “semiconductor chip 20″ hereinafter as long as it is not necessary to identify each of the semiconductor chips. Further, there is a case where the semiconductor chips 20a and 20b are generically termed “semiconductor chips 20 (20a and 20b)”. Note that, the multi-chip semiconductor device 21 according to the present embodiment has a structure in which the semiconductor chip 20a smaller than the semiconductor chip 20b is laminated on the semiconductor chip 20b.

Note that, in the following, members shared in common by the semiconductor chips 20a and 20b are given the same numbers and identified by using “a” or “b”. Therefore, as long as it is not necessary to identify the members which constitute the semiconductor chips 20a and 20b and which are shared in common by the semiconductor chips 20a and 20b, “a” and “b” are omitted or abbreviated in the same manner as the semiconductor chips 20 (20a and 20b).

The semiconductor chips 20 (20a and 20b) have different sizes but have substantially the same members. As illustrated in FIG. 2, each of the semiconductor chips 20 (20a and 20b) has a silicon substrate 1 (1a and 1b) (substrate), a semiconductor element 2 (2a and 2b) provided on a top surface of the silicon substrate 1 (1a and 1b), a first insulating film 3 (3a and 3b) formed so as to cover the semiconductor element 2 (2a and 2b), a second insulating film 4 (4a and 4b) formed on the first insulating film 3 (3a and 3b), and a wiring pattern 11 (11a and 11b) (conductive region) formed on the second insulating film 4 (4a and 4b). Further, each of the semiconductor chips 20 (20a and 20b) has a connecting electrode 12 (12a and 12b) which is connected with the wiring pattern 11 (11a and 11b) and penetrates the silicon substrate 1 (1a and 1b). Note that, for convenience of drawings, in FIG. 2, the semiconductor element 2 (2a and 2b) is indicated as a region (semiconductor-element formation region 2′ (2a′ and 2b′)) where the semiconductor element 2 (2a and 2b) is formed. Further, the silicon substrate 1 (1a and 1b) on which the semiconductor element 2 (2a and 2b) is formed, namely, the silicon substrate 1 (1a and 1b) and the semiconductor-element formation region 2′ (2a′ and 2b′) (the semiconductor element 2 (2a and 2b)) are generically termed a “semiconductor substrate 10 (10a and 10b)”.

Note that, in this specification, “top surface” of a semiconductor chip or “on” a semiconductor chip means a top surface side of a silicon substrate, namely, a side of a face on which semiconductor elements, an insulating film and the like are formed. Further, “bottom surface” of the semiconductor chip or “below” the semiconductor chip means a bottom surface side of the silicon substrate, namely, a backside of the face on which the semiconductor elements, the insulating film and the like are formed.

The first insulating film 3 covers the semiconductor elements 2 (the semiconductor-element formation region 2′) on the silicon substrate 1 so as to electrically or mechanically protect the semiconductor elements 2. Further, the second insulating film 4 covers the first insulating film 3 and prevents unnecessary electrification between the connecting electrode 12 and the silicon substrate 1. Note that, the connecting electrode 12 has a portion which is electrically connected with the semiconductor chip 20. Namely, in the semiconductor chip 20a, a connecting electrode 12a and semiconductor elements 2a in the semiconductor-element formation region 2a′ are electrically connected with each other. The semiconductor chip 20b has the same structure as the semiconductor chip 20a.

Further, it is preferable that at least one of the first insulating film 3 and the second insulating film 4 is a silicon oxide film or a silicon nitride film.

As illustrated in FIG. 2, the connecting electrode 12 (12a and 12b) is formed so that an upper end of the connecting electrode 12 (12a and 12b) is connected with the wiring pattern 11 (11a and 11b) and a lower end of the connecting electrode 12 (12a and 12b) protrudes from the bottom surface of the silicon substrate 1 (1a and 1b). The lower end of the connecting electrode 12 (12a and 12b) is a connection terminal (second connection region) 15 (15a and 15b) which allows connection with other semiconductor chip or an electrode other than a semiconductor chip (generically termed an “outside electrode” hereinafter). In this way, the connection terminal 15 is formed so as to protrude from the bottom surface of the silicon substrate 1, with a result that it is possible to put a buffer material 6 between the silicon substrate 1a of the semiconductor chip 20a and the wiring pattern 11b of the semiconductor chip 20b. The buffer material 6 is capable of preventing unnecessary electrification between the semiconductor chip 20a and the semiconductor chip 20b.

Further, the connecting electrode 12 (12a and 12b) has a conductive layer 5 (5a and 5b) which is electrically connected with the wiring pattern 11 (11a and 11b) and extends to the bottom surface of the silicon substrate 1 (1a and 1b). Further, at least a part of the connecting electrode 12 (12a and 12b) includes a filler (core) 9 (9a and 9b) which is surrounded by the conductive layer 5 (5a and 5b) on a cross section parallel to the top surface of the silicon substrate 1 (1a and 1b). Further, the second insulating film 4 is provided between the conductive layer 5 and the silicon substrate 1. The second insulating film 4 here is formed at the same time as formation of the second insulating film 4 on the first insulating film 3.

Further, as illustrated in FIG. 2, it is preferable that: the connection terminal 15 is covered with the conductive layer 5, particularly, the connection terminal 15 has a face (bottom face), connected with the outside electrode, which face is covered by the conductive layer 5. When the connection terminal 15 is not covered by the conductive layer 5, namely, when the filler 9 is exposed out of the connection terminal 15, a region connected with the outside electrode is small, and accordingly electric resistance between the semiconductor chip 20 and the outside electrode is increased. Such increase in the electric resistance causes an unfavorable drop in process speed of a device including the semiconductor chip 20, such as a computer and a communication device. Therefore, it is preferable that at least an externally connecting face of the connection terminal 15 is covered by the conductive layer 5. Namely, the conductive layer 5 is electrically connected with the wiring pattern 11 on the top surface of the semiconductor chip 20 and penetrates the semiconductor chip 20 (penetrates the silicon substrate 1) so as to form the connection terminal 15 on the bottom surface of the semiconductor chip 20.

Namely, the semiconductor chip 20 includes the penetrating hole 18 which penetrates the first insulating film 3 and the silicon substrate 1. The inner wall of the penetrating hole 18 is covered by the second insulating film 4 and the conductive layer 5 so that the second insulating film 4 is positioned nearer to the inner wall. A space surrounded by the conductive layer 5 in the penetrating hole 18 is filled with the filler 9.

Further, the wiring pattern 11 and the conductive layer 5 may be made of the same material. As a result, as described in the following <METHOD FOR PRODUCING SEMICONDUCTOR DEVICE>, in forming the conductive layer 5 serving as the connecting electrode 12, the conductive layer 5 is also formed on the top surface of the semiconductor chip 20 and patterned by etching and the like, thereby forming the wiring pattern 11. Namely, in order to form the wiring pattern 11, it is unnecessary to separately form, on the second insulating film 4, a conductive film other than the conductive layer 5, so that it is possible to reduce a time necessary for producing the semiconductor chip 20.

Further, preferable examples of the filler 9 include polymeric resin materials such as polyimide and epoxy resin, SiO₂ film-forming materials such as Spin On Glass (SOG). As described in the following <METHOD FOR PRODUCING SEMICONDUCTOR DEVICE>, with the filler 9, it is possible to reduce a time necessary for forming the connecting electrode 12, with a result that it is possible to reduce a time necessary for producing the semiconductor chip 20.

As described above, the wring pattern 11 is connected with the conductive layer 5 on the top surface of the semiconductor chip 20 (on the second insulating film 4). Further, on the top surface of the semiconductor chip 20, an output section (outer lead at an output side) and a connection region (first connection region) 13 for allowing electrical connection with the outside electrode are provided (see FIGS. 2 and 3). Each of the output section and the connection region 13 is a part of the wiring pattern 11.

Further, as illustrated in FIG. 3, on the top surface of the semiconductor chip 20a (top surface of the second insulating film 4a) having a rectangular shape, a plurality of wiring patterns 11a having substantially square shapes are provided so as to have a predetermined interval between each other. In the present embodiment, a side of the wiring pattern 11a has a length of approximately 10 to 100 μm.

Further, on the top surface of the semiconductor chip 20b (top surface of the second insulating film 4b) having a rectangular shape, a plurality of wiring patterns 11b having substantially rectangular shapes are provided so as to have a predetermined interval between each other. In the present embodiment, a long side of the wiring pattern 11b has a length of approximately 40 μm to 15 mm and a short side of the wiring pattern 11b has a length of approximately 10 to 100 μm. Further, the wiring patterns 11b are disposed so that the long sides of the wiring patterns 11b are parallel to long sides of the semiconductor chip 20b. Note that, in the semiconductor device according to the present invention, the long sides of the wiring patterns 11b are not necessarily parallel to the long sides of the semiconductor chip 20b, as long as the electrodes of laminated semiconductor devices (semiconductor devices adjacent to each other), namely, the semiconductor chips 20a and 20b according to the present embodiment, are disposed so as to correspond to each other.

Further, the wiring patterns 11b are disposed in a short side direction of the semiconductor chip 20b at the same interval as the wiring patterns 11a are disposed in a short side direction of the semiconductor chip 20a. In the present embodiment, the wiring patterns 11a and 11b are disposed at an interval ranging approximately from 10 μm to 1.5 mm.

Further, in the multi-chip semiconductor device 21 according to the present embodiment, the semiconductor chips adjacent to each other, namely, the semiconductor chips 20b and 20a are electrically connected with each other via connection between the connection region 13 of the semiconductor chip 20b and the connection terminal 15a of the semiconductor chip 20a.

Therefore, it is preferable that an area of the connection region 13 of the semiconductor chip 20b is larger than an end face of the connection terminal 15a of the semiconductor chip 20a. As a result, in mounting the semiconductor chip 20a on the semiconductor chip 20b, positioning is more freely performed. Namely, when the connection region 13 has the same size as that of the end face of the connection terminal 15a, the connection terminal 15a is displaced out of the connection region 13 unless the connection terminal 15a is exactly superimposed on the connection region 13. However, when the connection region 13 is larger than the end face of the connection terminal 15a, it is possible to connect the connection region 13 with the connection terminal 15a without exactly superimposing the connection terminal 15a on the connection region 13. As a result, it takes less time to layer the semiconductor chips, and accordingly it takes less time to produce the multi-chip semiconductor device. Further, even when the semiconductor chips have different sizes or the connecting electrodes of the semiconductor chips have different intervals, it is possible to layer the semiconductor chips so as to realize good electrification between the semiconductor chips.

Further, in the multi-chip semiconductor device 21 according to the present embodiment, the semiconductor chip 20a smaller than the semiconductor chip 20b is laminated on the semiconductor chip 20b. However, the multi-chip semiconductor device according to the present invention is not limited to this. Semiconductor chips having the same size as each other may be laminated or a semiconductor chip having larger size than another semiconductor chip may be laminated on another semiconductor chip.

However, when the semiconductor substrate 10a is smaller than the semiconductor substrate 10b, namely, when the semiconductor chip 20a is smaller than the semiconductor chip 20b, there is such an advantage that positioning of the semiconductor substrate 10a and the semiconductor substrate 10b depends on a width of a long side of the wiring pattern 11b and accordingly the positioning is performed more freely. Therefore, it is more preferable that the size in a vertical direction and the size in a lateral direction of the semiconductor substrate 10a which should be laminated range from the sizes identical with those of the semiconductor substrate 10b to approximately one-third of the sizes of the semiconductor substrate 10b.

Further, when the silicon substrates 1a and 1b in the laminated semiconductor chips 20a and 20b are identical with each other, the present invention may be arranged so that: regions used for connection is provided around holes which do not penetrate the silicon substrate 1 (concave section 8) and the semiconductor chips 20a and 20b are laminated so as not to be entirely superimposed on each other, thereby connecting the semiconductor chips 20a and 20b.

<Method for Producing Semiconductor Device>

A method according to the present invention for producing a semiconductor device should include the steps of (i) forming, in a substrate having semiconductor elements on a top surface of the substrate, a concave section which has an opening at the top surface of the substrate and whose inner wall is covered by a conductive layer (a concave section forming step), (ii) filling the concave section with a filler (a filling step), and (iii) exposing the conductive layer from a bottom surface of the substrate (an exposing step).

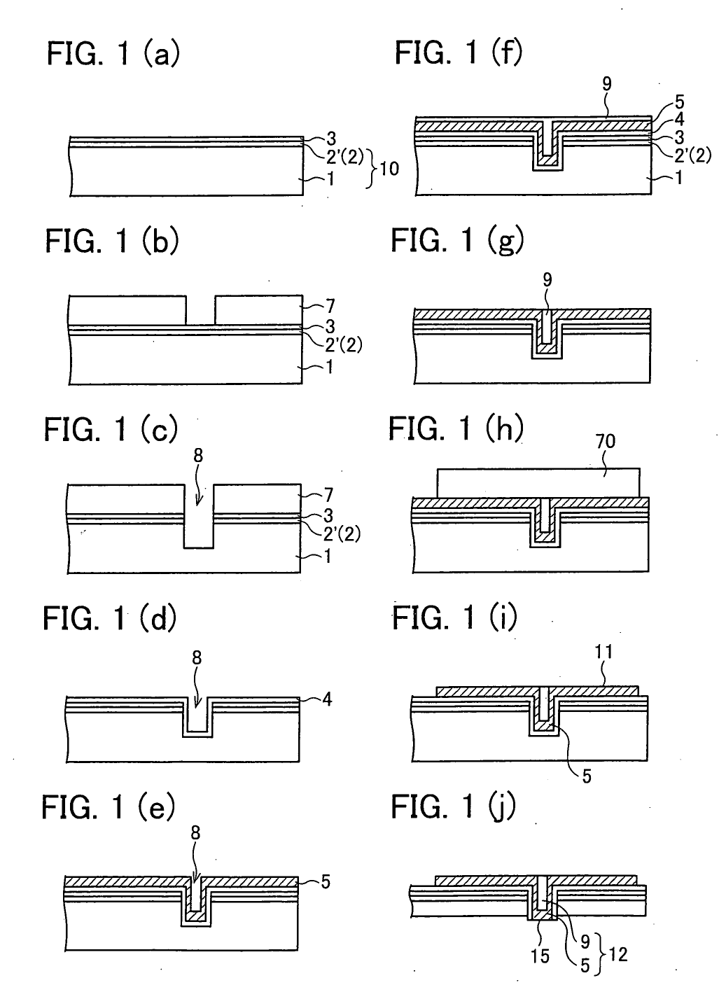

With reference to FIGS. 1(a) to 1(j), the following explains a method according to the present embodiment as an example of the foregoing method.

FIGS. 1(a) to 1(j) are cross sectional views illustrating a method according to the present embodiment for producing a semiconductor device.

In the method according to the present embodiment, first, as illustrated in FIG. 1(a), the first insulating film 3 is formed on the top surface of the semiconductor substrate 10. Note that, the semiconductor substrate 10 is obtained by providing semiconductor elements 2 (semiconductor-element formation region 2′ in the drawings) on the silicon substrate 1 (substrate). The first insulating film 3 is formed on the top surface of the semiconductor substrate 10 so as to cover the semiconductor-element formation region 2′ (semiconductor elements 2).

As the first insulating film 3, an insulating film having etching selectivity with respect to silicon (Si), such as a silicon nitride (Si₃N₄) film or a silicon oxide (SiO₂) film, is suitable. Further, in the present embodiment, a silicon nitride (Si₃N₄) film whose thickness is 600 nm is formed as the first insulating film 3 in accordance with plasma CVD using SiH₄ and NH₃.

Next, as illustrated in FIG. 1(c), the concave section 8 is formed in the silicon substrate 1 (corresponding to FIGS. 1(b) to 1(e), the concave section forming step). A method for forming the concave section 8 is not particularly limited. As an example, the following explains a method using photolithography and etching with reference to FIGS. 1(b) to 1(e).

First, as illustrated in FIG. 1(b), a photoresist layer 7 is formed on the first insulating film 3. Next, a pattern used to form the later-mentioned concave section 8 (see FIG. 1(c)) is formed on the photoresist layer 7 in accordance with photolithography (corresponding to FIG. 1(b)).

Next, the concave section 8 is formed in accordance with etching by using, as a mask, the photoresist layer 7 on which the pattern has been formed (corresponding to FIG. 1(c)). At that time, the silicon substrate 1, the semiconductor-element formation region 2′, and the first insulating film 3 are etched, so that there is formed the concave section 8 which penetrates the first insulating film 3 and the semiconductor-element formation region 2′ but does not penetrate the silicon substrate 1. Namely, an opening of the concave section 8 is formed on the top surface of the first insulating film 3 and a bottom of the concave section 8 is formed in the silicon substrate 1. In other words, the concave section 8 is formed so that: a length between the top surface of the first insulating film 3 and the bottom of the concave section 8 is longer than a length obtained by adding the thickness of the semiconductor-element formation region 2′ and the thickness of the first insulating film 3, and is shorter than a length obtained by adding the thickness of the silicon substrate 1, the thickness of the semiconductor-element formation region 2′, and the thickness of the first insulating film 3. The depth of the concave section 8 is not particularly limited as long as the concave section 8 meets the foregoing conditions. Further, the depth of the concave section 8 at that time may be suitably set because a preferable value is variable depending on conditions under which semiconductor chips are laminated.

Note that, in FIGS. 1(c) and 1(d), the inner wall of the concave section 8 is not covered by the conductive layer 5. However, for convenience of explanation, a term concave section” is used.

Next, the photoresist layer 7 is removed from the top surface of the first insulating film 3, and then the second insulating film 4 is formed so as to cover the first insulating film 3 and the inner wall (side wall and bottom) of the concave section 8 (corresponding to FIG. 1(d)). The second insulating film may be made of the same material as that of the first insulating film. Examples of the second insulating film include a silicon oxide (SiO₂) film, a silicon nitride (Si₃N₄) film, and a film including a laminated structure constituted of the silicon oxide (SiO₂) film and the silicon nitride (Si₃N₄) film. In the present embodiment, as the second insulating film, a silicon oxide film whose thickness is 100 to 200 nm is formed by using SiH₄/N₂O gas in accordance with plasma CVD. With plasma CVD, it is possible to form an insulating film splendid in coverage and film quality even when the film is thin.

Next, a barrier film (not shown) is formed on the second insulating film 4 including the inside (side wall and bottom) of the concave section 8 in accordance with PVD or CVD so as to prevent diffusion of the conductive layer 5, and then a metal seed layer (not shown) is formed on the barrier layer.

Next, as illustrated in FIG. 1(e), the top surface of the second insulating film 4 (including a portion on the inside of the concave section 8) is covered by the conductive layer 5 (corresponding to concave section forming step and conductive region forming step). As a result, the concave section 8 whose inner wall is covered by the conductive layer 5 is formed. A preferable example of a material for the conductive layer 5 is at least one metal selected from aluminum (Al), copper (Cu), nickel (Ni) and the like or an alloy including said at least one metal (e.g. Al—Si alloy, Cu alloy, Ni alloy, and the like).

Examples of a method for forming the conductive layer 5 include metal plating, CVD, PVD and the like. With these methods, it is possible to form the conductive layer 5 speedily and evenly.

The formation of the concave section 8 whose inner wall is covered by the conductive layer 5 means to adjust the thickness of the conductive layer 5 so that the concave section 8 is not entirely filled with the conductive layer 5. Namely, in the concave section 8 having the conductive layer 5 formed therein, a space should be formed so that the space can be filled with the filler 9.

The thus formed concave section 8 has the second insulating film 4 formed between the conductive layer 5 and the silicon substrate 1. With the second insulating film 4, it is possible to prevent unnecessary electrification between the conductive layer 5 and the silicon substrate 1.

The concave section forming step can be expressed also as follows: the concave section forming step includes the sub-steps of (i) forming the concave section 8 from the top surface of the silicon substrate 1 and (ii) covering the inside of the concave section 8 with the conductive layer. Further, “forming the concave section 8” means forming a hole which does not penetrate the silicon substrate 1.

Further, in order to electrically connect the connecting electrode 12 and the semiconductor elements 2 in the semiconductor-element formation region 2′, a general photolithography technique and a general etching technique can be used. To be specific, the second insulating film 4 is partially removed by etching so that the connecting electrode 12 is connected with a portion which should be connected with the connecting electrode 12. Thereafter, by forming the conductive layer 5, a pattern electrically connecting the connecting electrode 12 with the semiconductor elements 2 is formed. The portion which should be connected with the connecting electrode 12 means an electrode provided on the semiconductor-element formation region 2′ for example.

Next, the filling step for filling the thus formed concave section 8 with the filler 9 is performed. Next, the exposing step for exposing the conductive layer 5 from the bottom surface of the silicon substrate 1 is performed.

First, as illustrated in FIG. 1(f), the concave section 8 whose inner wall is covered by the conductive layer 5 is filled with the filler 9. By filling the concave section 8 with the filler 9 in this manner, the top surface of the semiconductor chip 20 becomes flat. As a result, it becomes easy to form and pattern a photoresist layer 70 in the following steps (corresponding to FIGS. 1(h) to 1(i)). Properties of the filler 9, such as conductivity, is not particularly limited as long as the filler 9 can accelerate formation of the connecting electrode 12. Further, a method for filling is not particularly limited as long as the method allows the concave section 8 to be filled with the filler 9.

Therefore, the present invention may be arranged so that a filler 9 which is a solid body is shaped so as to fit into the space of the concave section 8 and then the solid filler 9 is embedded in the concave section 8 so that the concave section 8 is filled with the filler 9. However, it is preferable that the filler 9 is made of a material which has fluidity in filling the concave section 8 and which is capable of being cured after the filling. The material having fluidity causes the top surface of the semiconductor chip to be flat in filling the concave section 8 and causes the concave section 8 to be filled so that there is no gap, thereby suppressing generation of grooves and voids (holes).

Examples of the filler having such fluidity include polymeric resin materials, such as polyimide and epoxy, and SiO₂ film-forming materials, such as SOG. In order to fill the concave section 8 with these polymeric resin materials, a method of application such as spin coating should be used. Further, these fillers may be cured in accordance with thermal cure or UV irradiation after the concave section 8 is filled with these fillers. Note that, in the present embodiment, an SOG material is applied on the conductive layer 5 in accordance with spin application at rotational frequency of 1500 rpm and then heated in N₂ atmosphere at 200° C. for 30 minutes.

After filling the concave section 8 with the filler 9 as described above, an unnecessary portion of the filler 9 is removed as illustrated in FIG. 1(g). As a result, the conductive layer 5 is exposed on the top surface of the semiconductor chip 20. A favorable example of a method for removing the filler 9 at that time is etch-back process using a dry etching technique.

Next, the wiring pattern 11 is formed on the top surface of the semiconductor chip. A favorable example of a method for forming the wiring pattern 11 is photolithography and etching. Namely, a photoresist layer 70 is formed and then a pattern used to form the wiring pattern 11 is formed on the photoresist layer 70 in accordance with photolithography (corresponding to FIG. 1 (h), conductive region forming step).

Then, the second insulating film 4 is etched by using the photoresist layer 70 as a mask, so that the wiring pattern 11 is formed (corresponding to FIG. 1(i)). At that time, the wiring pattern 11 is formed so as to be connected with the conductive layer 5 in the concave section 8.

Further, at that time, as described above with reference to FIGS. 2 and 3, the wiring pattern 11 (wiring pattern 11b) of the semiconductor chip 20 (semiconductor chip 20b in FIGS. 2 and 3) positioned as a lower layer when semiconductor chips are laminated is formed so as to include a connecting region (connecting region 13) which allows connection with the connecting electrode 12 (connecting electrode 12a) of the semiconductor chip 20 (semiconductor chip 20a) which should be laminated on the semiconductor chip 20 positioned as a lower layer.

Further, as described above with reference to FIGS. 2 and 3, it is preferable that: the connecting region (connecting region 13) has a larger area than a portion which is a lower side of the connecting electrode 12 (connecting electrode 12a) of the semiconductor chip 20 (semiconductor chip 20a) positioned as an upper layer and which is to be connected with the semiconductor chip 20 (semiconductor chip 20b) positioned as a lower layer, namely, the connecting region (connecting region 13) has a larger area than the bottom face of the connecting electrode 12 (end face of the connecting region 13) of the semiconductor chip 20 positioned as an upper layer. As a result, positioning of the semiconductor chips 20a and 20b can be performed more freely.

Next, the exposing step for exposing the conductive layer 5 from the bottom surface of the semiconductor chip 20, namely, the bottom surface of the silicon substrate 1, is performed. At that time, the bottom surface of the semiconductor chip 20 should be partially removed in a direction of the top surface side of the semiconductor chip 20 so that the conductive layer 5 is exposed (corresponding to FIG. 1(j)). Namely, the silicon substrate 1 and the second insulating film 4 are partially removed from the bottom surface side of the silicon substrate 1. At that time, examples of a method for partially removing the silicon substrate 1 and the second insulating film 4 include CMP (Chemical Mechanical Polishing), chemical polishing, mechanical polishing, wet etching, plasma etching, gas etching, and combinations thereof.

With the step, the penetrating hole 18 which penetrates the silicon substrate 1 from the top surface thereof to the bottom surface thereof is formed and the connecting electrode 12 is formed in the penetrating hole 18.

Note that, when a non-conductive material such as a resin material is used as the filler 9, it is preferable that the filler 9 is not exposed from the bottom surface of the silicon substrate 1 in the exposing step.

In the present embodiment, the exposing step is a step of partially removing the semiconductor chip 20 from the bottom surface into a direction of the top surface so that the conductive layer 5 is exposed from the bottom surface of the silicon substrate 1.

However, the exposing step is not particularly limited as long as the step allows for electrification between the top surface and the bottom surface of the semiconductor chip 20 by exposing the conductive layer 5 from the bottom surface of the semiconductor chip 20. Namely, the step may be as follows.

A hole penetrating the silicon substrate 1 is formed and an inner wall of the hole is covered by the second insulating film 4 in the concave section forming step. As a result, a hole which penetrates the silicon substrate 1 and whose inner wall is covered by the second insulating film 4 is formed. After that, an opening of the hole at the bottom surface of the silicon substrate 1 is sealed by a sealing material having a film shape or the like, so that the bottom of the hole is formed. Then, the conductive layer 5 is formed so as to cover the inner wall (side wall and bottom) of the hole. With this process, too, it is possible to form a concave section whose opening is positioned at the top surface of the silicon substrate 1 and whose inner wall is covered by the conductive layer 5.

Next, the filling step for filling the thus formed concave section with the filler 9 is performed. The filling step has already been explained above. Then, the sealing material may be peeled off so as to expose the conductive layer 5 from the bottom surface of the silicon substrate 1, which corresponds to the exposing step.

However, in order to obtain a thin semiconductor device, it is preferable that: as described above with reference to FIG. 1(j), the connecting electrode 12 is formed from the top surface of the semiconductor chip 20 to the inside of the silicon substrate 1 and then the silicon substrate 1 is partially removed, thereby exposing the conductive layer 5 from the bottom surface of the silicon substrate 1. The reason is as follows.

An object of a multi-chip semiconductor device obtained by laminating semiconductor chips is to form multiple semiconductor elements in a smaller area. Therefore, it is preferable to cause the semiconductor chip 20 which should be laminated to be as thin as possible. However, when the silicon substrate 1 is initially made thin, there is a case where the silicon substrate 1 does not have sufficient strength and accordingly the silicon substrate 1 breaks when the penetrating hole 18 is formed. Further, when the silicon substrate 1 is thick, it is technically difficult to cause a hole to penetrate the silicon substrate 1 as far as the bottom surface of the silicon substrate 1. Further, even when the hole penetrates the silicon substrate 1, the thick silicon substrate 1 makes it very difficult to evenly coat the inside of the hole with the conductive layer 5.

Further, as described above, the lower end of the connecting electrode 12 protrudes from the bottom surface of the silicon substrate 1. As a result, it is possible to put the buffer material 6 between the semiconductor chips 20a and 20b. In order to cause the lower end of the connecting electrode 12 to protrude from the back surface of the silicon substrate 1, etch-back based on RIE (reactive ion etching), wet etching with a chemical solution, and the like as well as polishing from the back surface of the silicon substrate 1 should be performed. With these methods, it is possible to partially remove only the silicon substrate 1 without partially removing the connecting electrode 12. Further, etch-back based on RIE is preferable because RIE is splendid in process speed and selectivity.

As described above, the method according to the present invention for producing a semiconductor device includes the step of forming a connecting electrode, said step further including the sub-steps of: (i) forming a concave section by forming an opening on the top surface of the substrate and coating an inner wall of the opening with a conductive layer (concave section forming step); and (ii) exposing the conductive layer from a bottom surface of the substrate (exposing step).

Therefore, with the method, it takes less time to form the connecting electrode than a conventional method for producing a semiconductor device. As such, it is possible to reduce a time necessary for production of a semiconductor device.

Further, it is preferable that the method according to the present invention further includes the step of filling the concave section with a filler made of a material different from a material of the conductive layer.

With the method, the concave section is filled with the filler, so that the top surface of the semiconductor device is made flatter. As a result, in forming the wiring pattern after the step of filling the concave section, namely, in patterning in accordance with photolithography, resist does not intrude a space, so that patterning is more easily performed. Further, because the space is filled with the filler, it is possible to reduce breakage caused by expansion due to heat generation when the semiconductor device is completed and then operated.

Further, it is preferable that: in the sub-step (ii), the back surface of the substrate is partially removed in a direction of the top surface of the substrate so as to expose the conductive layer.

With the arrangement, the sub-step (ii) allows the substrate to be thin. Namely, before the sub-step (ii), it is unnecessary to make the substrate thin. Therefore, in steps before the sub-step (ii), the substrate is kept thick, so that it is possible to keep strength of the substrate and prevent the substrate from being damaged or prevent similar problems.

Further, it is preferable that the sub-step (i) includes a process of extending the conductive layer from the inner wall of the opening on the top surface of the substrate to vicinity of the opening so as to form a conductive region.

The conductive region serves as a connecting region which is connected with other semiconductor device or an electrode other than a semiconductor device. As a result, it is unnecessary to form other conductive layer serving as such a connecting region, so that it is possible to further reduce a time necessary for production of a semiconductor device.

Further, it is preferable that: in the sub-step (i), the conductive layer is formed in accordance with at least one of metal plating, CVD, and PVD.

With the arrangement, it is possible to further reduce a time necessary for production of the conductive layer.

The semiconductor device according to the present invention includes a substrate and semiconductor elements provided on a top surface of the substrate, said substrate including (i) a first connecting region provided on the top surface of the substrate so as to allow connection with an outside electrode, (ii) a second connecting region provided on a back surface of the substrate so as to allow connection with an outside electrode, and (iii) a connecting electrode which penetrates the substrate and allows electrical connection with the first connecting region and the second connecting region, at least a part of said connecting electrode including a core and a conductive layer surrounding the core in a cross sectional face parallel to the top surface of the substrate, and said core being made of a material different from a material of the conductive layer.

With the arrangement, the connecting electrode includes the core made of the material different from the material of the conductive layer. Therefore, it takes less time to form the connecting electrode than a case where the inside of the connecting electrode is made of the same material as the conductive layer.

Further, it is preferable that the second connecting region is an end face of the connecting electrode and the end face of the connecting electrode is covered by the conductive layer.

With the arrangement, the second connecting region is electrically connected with the outside electrode via a larger area. As a result, electric resistance at a portion connected with the outside electrode becomes small. Therefore, when the semiconductor device is mounted on a computer and the like, process speed of the computer and the like increases.

The laminated semiconductor device according to the present invention is obtained by laminating a plurality of semiconductor devices, and semiconductor devices adjacent to each other, out of the semiconductor devices, are electrically connected with each other via a first connecting region on one of the semiconductor devices adjacent to each other and a second connecting region on another of the semiconductor devices adjacent to each other.

With the arrangement, the laminated semiconductor device according to the present invention includes a semiconductor device including an electrode which penetrates the substrate. It is easy to laminate such semiconductor device, so that it is easy to produce the laminated semiconductor device. Further, it takes less time to produce the semiconductor device, so that it takes less time to produce the laminated semiconductor device including the semiconductor device.

Further, it is preferable that: in the laminated semiconductor device, one of the semiconductor devices has a first connecting region larger than a second connecting region of other one of the semiconductor devices laminated on said one of the semiconductor devices.

With the arrangement, positioning of the semiconductor devices adjacent to each other is performed more freely, so that it takes less time to perform the positioning.

The semiconductor device according to the present invention is favorably applicable to a semiconductor chip constituting a laminated semiconductor device. The method according to the present invention allows the semiconductor device to be produced in a short time.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A method for producing a semiconductor device, comprising the step of forming, in a substrate having semiconductor elements on a top surface of the substrate, a connecting electrode for electrically connecting the semiconductor elements with an outside electrode,
said step further including the sub-steps of:
(i) forming a concave section by forming an opening on the top surface of the substrate and coating an inner wall of the opening with a conductive layer; and
(ii) exposing the conductive layer from a bottom surface of the substrate.

2. The method as set forth in claim 1, further comprising the step of filling the concave section with a filler made of a material different from a material of the conductive layer.

3. The method as set forth in claim 1, wherein: in the sub-step (ii), the back surface of the substrate is partially removed in a direction of the top surface of the substrate so as to expose the conductive layer.

4. The method as set forth in claim 1, wherein the sub-step (i) includes a process of extending the conductive layer from the inner wall of the opening on the top surface of the substrate to vicinity of the opening so as to form a conductive region.

5. The method as set forth in claim 1, wherein: in the sub-step (i), the conductive layer is formed in accordance with at least one of metal plating, CVD, and PVD.

6. A semiconductor device, comprising a substrate and semiconductor elements provided on a top surface of the substrate,
said substrate including (i) a first connecting region provided on the top surface of the substrate so as to allow connection with an outside electrode, (ii) a second connecting region provided on a back surface of the substrate so as to allow connection with an outside electrode, and (iii) a connecting electrode which penetrates the substrate and allows electrical connection with the first connecting region and the second connecting region,
at least a part of said connecting electrode including a core and a conductive layer surrounding the core in a cross sectional face parallel to the top surface of the substrate, and
said core being made of a material different from a material of the conductive layer.

7. The semiconductor device as set forth in claim 6, wherein the second connecting region is an end face of the connecting electrode and the end face of the connecting electrode is covered by the conductive layer.

8. A laminated semiconductor device, obtained by laminating a plurality of semiconductor devices,
each of said semiconductor devices including a substrate and semiconductor elements provided on a top surface of the substrate,
said substrate including (i) a first connecting region provided on the top surface of the substrate so as to allow connection with an outside electrode, (ii) a second connecting region provided on a back surface of the substrate so as to allow connection with an outside electrode, and (iii) a connecting electrode which penetrates the substrate and allows electrical connection with the first connecting region and the second connecting region,
at least a part of said connecting electrode including a core and a conductive layer surrounding the core in a cross sectional face parallel to the top surface of the substrate,
said core being made of a material different from a material of the conductive layer, and
semiconductor devices adjacent to each other, out of said semiconductor devices, being electrically connected with each other via a first connecting region on one of said semiconductor devices adjacent to each other and a second connecting region on another of said semiconductor devices adjacent to each other.

9. The laminated semiconductor device as set forth in claim 8, wherein the second connecting region is an end face of the connecting electrode and the end face of the connecting electrode is covered by the conductive layer.

10. The laminated semiconductor device as set forth in claim 8, wherein one of the semiconductor devices has a first connecting region larger than a second connecting region of other one of the semiconductor devices laminated on said one of the semiconductor devices.
